(19) United States
(12) Patent Application Publication
(10) Pub. No.: US 2014/0029638 A1
(43) Pub. Date: Jan. 30, 2014

(54) BLUE LASER PUMPED GREEN LIGHT SOURCE FOR DISPLAYS

(71) Applicant: Corporation for Laser Optics Research, (US)

(72) Inventors: David Welford, Hathorne, MA (US); Masayuki Karakawa, Newmarket, NH (US)

(73) Assignee: CORPORATION FOR LASER OPTICS RESEARCH, Portsmouth, NH (US)

(21) Appl. No.: 13/802,286

(22) Filed: Mar. 13, 2013

Related U.S. Application Data
(63) Continuation of application No. 12/500,828, filed on Jul. 10, 2009, now abandoned.
(60) Provisional application No. 61/079,599, filed on Jul. 10, 2008.

(51) Int. Cl. H01S 5/026

(52) U.S. Cl. CPC H01S 5/0262
USPC 372/50.1

(57) ABSTRACT

The invention relates to light sources and displays incorporating blue laser pumped light sources that provide green light. According to a first aspect of the invention, a green light source includes a semiconductor diode laser emitting light in an optical path having a dominant wavelength within the blue spectral region, a substrate positioned in the optical path of the semiconductor diode laser, and a material coupled to the substrate. The material is selected to absorb light emitted by the semiconductor diode laser and, in response, to emit light having a dominant wavelength within the green spectral region. According to a second aspect of the invention, an apparatus includes a lighting module for a display, the lighting module includes an array of red laser light sources, an array of blue laser light sources, and an array of green light sources according to the first aspect of the invention.

### CROSS-REFERENCE TO RELATED APPLICATIONS

This application claims the benefit of U.S. Provisional Patent Application No. 61/079,599 filed Jul. 10, 2008, which is hereby incorporated by reference herein in its entirety.

### BACKGROUND OF THE INVENTION

Red, green and blue (RGB) lasers offer demonstrable benefits over other light sources for high-performance imaging applications. Greater color saturation, contrast, sharpness, and color-gamut are among the most compelling attributes distinguishing laser displays from conventional imaging systems employing lamps. In spite of these performance advantages, however, market acceptance of laser display technology remains hindered as a result of its higher cost, lower reliability, larger package size and greater power consumption when compared to an equivalent lumen output lamp-driven display.

To compare laser technology with conventional technologies, it is instructive to examine two fundamental parameters which relate to their ultimate practicality. The first parameter can be defined as optical efficiency—in this case, the lumens of output per watt of input to the light source. The second is cost compatibility, that is, the extent to which the technology in question yields a cost effective solution to the requirements of a specific application.

Based on these parameters, a red/green/blue (RGB) semiconductor/microlaser system, consisting of three lasers or laser arrays, each operating at a fundamental color, appears to be the most efficient, high brightness, white light source for display applications to date. Semiconductor laser operation has been achieved from the ultraviolet (“UV”) to the infrared (“IR”) range of the spectrum, using device structures based on InGaAlN, InGaAlP, and InGaAlAs material systems. Desirable dominant wavelength ranges for the three laser arrays are 610-635 nm for red, 525-540 nm for green, and 445-470 nm for blue. An optical source with this spectrum provides a greater color gamut than a conventional arc lamp approach and projection technology which uses blackbody radiation.

One challenge in providing RGB laser lighting is the lack of a suitable semiconductor laser emitting green light. Instead, green light must be provided by a microlaser or green light emitting diode. Microlaser require more space and both microlasers and LEDs require greater power consumption per lumen output than semiconductor lasers. Thus, a need exists in the art for a cost-effective, compact semiconductor-laser based green lighting source for a display.

### SUMMARY OF THE INVENTION

The invention is directed to blue laser pumped green light sources for displays. According to a first aspect of the invention, an apparatus for emitting green light includes a semiconductor diode laser emitting light in an optical path having a dominant wavelength within the blue spectral region, a substrate positioned in the optical path of the semiconductor diode laser, and a material coupled to the substrate. The material is selected to absorb light emitted by the semiconductor diode laser and, in response, to emit light having a dominant wavelength within the green spectral region. In some embodiments, the material emits light as an amplified spontaneous emission.

In some embodiments, the material includes a phosphor deposited on a surface of the substrate. In some implementations, the phosphor includes a semiconductor material having a band gap in the green spectral region. In some implementations, the phosphor includes at least one of a CdS, a CdSe, a ZnS, or a ZnO composition. In some implementations, the phosphor includes a composition having the form CdSₓSe₁₋ₓ.

In some embodiments, the material includes a rare-earth ion dopant. In some implementations, the dopant includes one of a Pr³⁺, Nd³⁺, Sm³⁺, Tb³⁺, Ho³⁺, Er³⁺.

In some embodiments, the apparatus includes one or more components for affecting light, such as an optical filter, an output coupler, and/or a component for directing light emitted by the material in a desired direction. The optical filter is placed beyond the substrate in the optical path to filter out light not in the green spectral region. The output coupler is placed beyond the substrate in the optical path to reflect at least a portion of light in the green spectral region back towards the substrate to generate quasi-resonant green light. In some embodiments, the material is coupled to a first side of the substrate; and the apparatus includes a reflective surface coating an opposing side of the substrate. In some embodiments, the substrate includes a Mie scattering matrix including spherical particles, the material being dispersed between the spherical particles.

According to a second aspect of the invention, an apparatus includes at least one lighting module for a display. The at least one lighting module includes an array of red laser light sources, an array of blue laser light sources, and an array of green light sources according to the first aspect of the invention described above. In some embodiments, the lighting modules are configured to emit light, which when combined, is substantially white.

In some embodiments, at least one of the array of red laser lights sources and the array of blue laser light sources includes at least one laser light source that has a dominant wavelength λ₀ᵢ and a spectral bandwidth ΔXᵢ. The dominant wavelength of the at least one laser light source of the array is wavelength-shifted with respect to the dominant wavelength of at least one other laser light source of the array. Emissions from said laser light sources of the array, when combined, have an ensemble spectrum Λ with an overlap parameter γ= Δ̅λ̅ᵢ̅/ S̅ᵢ̅, where Δ̅λ̅ᵢ̅ is a mean spectral bandwidth of the laser light source array, S̅ᵢ̅ is a mean wavelength shift between the dominant wavelengths λ₀ᵢ of the at least one laser light source and the at least one other laser light source, and Δ̅λ̅ᵢ̅ and S̅ᵢ̅ of the array is selected so that γ≧1.

In some embodiments, the apparatus includes a light guide and an array of liquid crystal light modulators. The at least one lighting module is disposed about the perimeter of the light guide for injecting light into the light guide. The array of liquid crystal light modulators modulates light exiting the light guide.

Further features and advantages of the present invention will be apparent from the following description of preferred embodiments and from the claims.

### BRIEF DESCRIPTION OF THE DRAWINGS

The following figures depict certain illustrative embodiments of the invention in which like reference numerals refer to like elements. These depicted embodiments are to be understood as illustrative of the invention and not as limiting in any way.

FIG. 1 is a top view of an exemplary bandwidth-enhanced laser light source with n lasing elements;

FIG. 2 is a schematic cross-sectional view of a color channel of a projection display incorporating the bandwidth-enhanced laser light source;

FIG. 3 shows an alternative embodiment of the bandwidth-enhanced laser light source incorporated in a projection display;

FIG. 4 shows schematically a full color RGB projection display incorporating the bandwidth-enhanced laser light sources in each color channel;

FIG. 5 shows schematically the spectral emission and the ensemble spectrum of five exemplary emitters having a mean spectral overlap parameter γ>1;

FIG. 6 shows schematically the spectral emission and the ensemble spectrum of five exemplary emitters having a mean spectral overlap parameter γ=1;

FIG. 7 shows schematically the spectral emission and the ensemble spectrum of five exemplary emitters having a mean spectral overlap parameter γ<1;

FIG. 8 shows schematically the spectral emission and the ensemble spectrum of five exemplary emitters having a mean spectral overlap parameter γ<<1;

FIG. 9 shows schematically, a laser illuminated backlight for a liquid crystal flat panel display;

FIGS. 10A and 10B show schematically first and second illustrative configurations of a laser module for introducing laser light into the backlight of FIG. 9; and

FIGS. 11A and 11B show schematically first and second illustrative blue-diode laser pumped green light sources suitable for inclusion in the laser modules of FIGS. 10A and 10B, according to an embodiment of the invention.

### DETAILED DESCRIPTION OF CERTAIN ILLUSTRATED EMBODIMENTS

The invention is directed to a bandwidth-enhanced laser light source for displays. In particular, the laser light source described herein can reduce speckle in display applications.

As used herein, the “dominant wavelength” of a light source is the wavelength at which the intensity of the light emitted from the light source is greatest. In some embodiments, in which the light source has a generally Gaussian emission spectrum, the dominant wavelength is substantially equal to the center wavelength of the light source, that is, the wavelength around which the spectral bandwidth of the light source is centered. In other embodiments, the spectral output of the light source includes peaks of output intensity at multiple wavelengths. In such embodiments, the dominant wavelength is the wavelength with the highest intensity emission, regardless of its position within the spectral bandwidth of the light source.

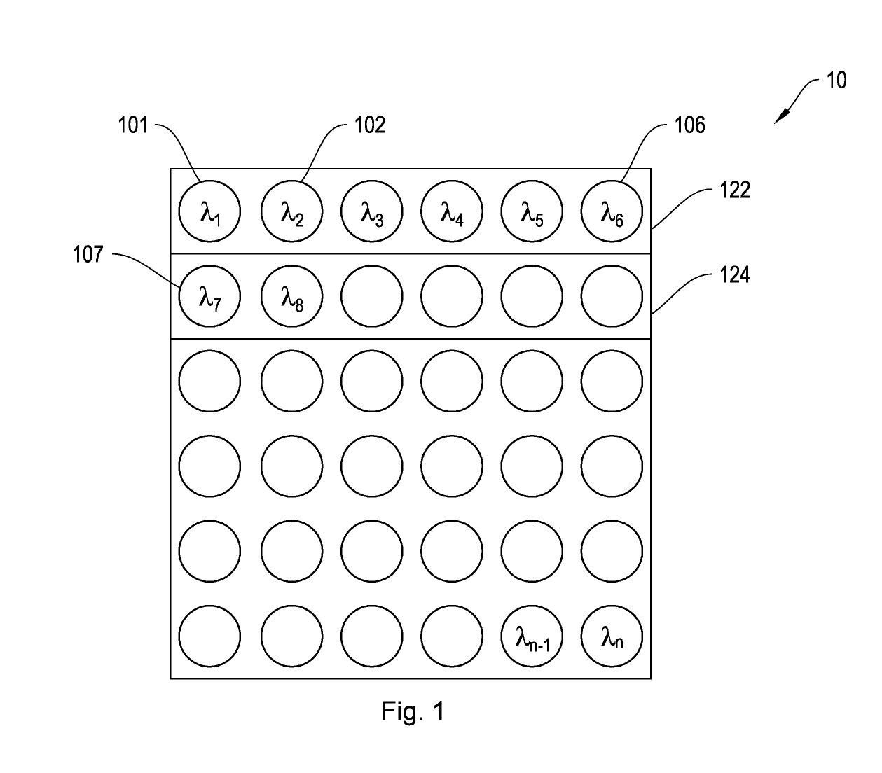

Referring now to FIG. 1, bandwidth-enhanced laser light is produced from a two-dimensional (2-D) array 10 of spatially separated, discrete emitters 101, 102, . . . of laser radiation, wherein each emitter 101, 102, . . . has a respective spectral bandwidth Δλᵢ that includes a dominant wavelength equal to some arbitrary red, green, or blue wavelength λ₀ᵢ. The elements of the array 10 are designed to have slightly different dominant wavelengths, thereby creating an ensemble bandwidth ΔΛ which is greater than the bandwidth Δλvi, of any individual emitter in the array 10. By engineering precisely the amount of ensemble bandwidth ΔΛ required for the cancellation of speckle, the quasi-monochromatic property responsible for the appearance of fully-saturated color is preserved.

The exemplary compact 2-D bandwidth-enhanced laser array 10 depicted in FIG. 1 can be constructed either from a two-dimensional array of vertical-cavity surface-emitting lasers (VCSEL) or by superposition of 1-D edge emitting laser bars 122, 124, . . . , with each laser bar having multiple laser emitters 101, 102, . . . , 106. VCSEL's tend to have a superior overall efficiency due to their higher beam quality. Edge emitting laser bars can include tens to hundreds of closely spaced emitters formed on the same bar; alternatively, individual laser edge emitters can be laid side-by-side to make the 1-D laser bar. The bars can be quite thin by at least partially removing the substrate on which the laser emitters are grown. The bars can be electrically connected in series, thereby providing a substantially identical optical power emitted by each element. Array bandwidths of 10 nm or more can be achieved by selecting diode emitters with different peak emission wavelengths, as described below. It has be observed that not all the lasing elements need to have different wavelengths from one another, and that wavelength can repeat across the 2-D array as long as the emitters do not strongly interact and provide the desired assembly bandwidth of approximately 1-10 nm.

The emission wavelength of semiconductor diode laser emitters 101, 102, . . . depicted in FIG. 1 may be selected and/or adjusted by one of the following methods: (1) building the 2-D array from stacked 1-D bars, with the wavelength range of each bar selected so as not to coincide with the wavelength of another bar, with the 2-D array covering the desired assembly wavelength range Λ; (2) varying the composition of the active layer across the device structure during crystal growth; (3) varying the thickness and/or composition of the quantum well (QW) layer in a QW structure during crystal growth; (4) varying the spectral response of the end mirrors across the gain curve of the laser (this may also include an etalon with a transmission coefficient that varies across the emitter array 10; and/or (5) non-uniformly heating or cooling the array 10 to introduce temperature gradient and thereby a shift in the bandgap.

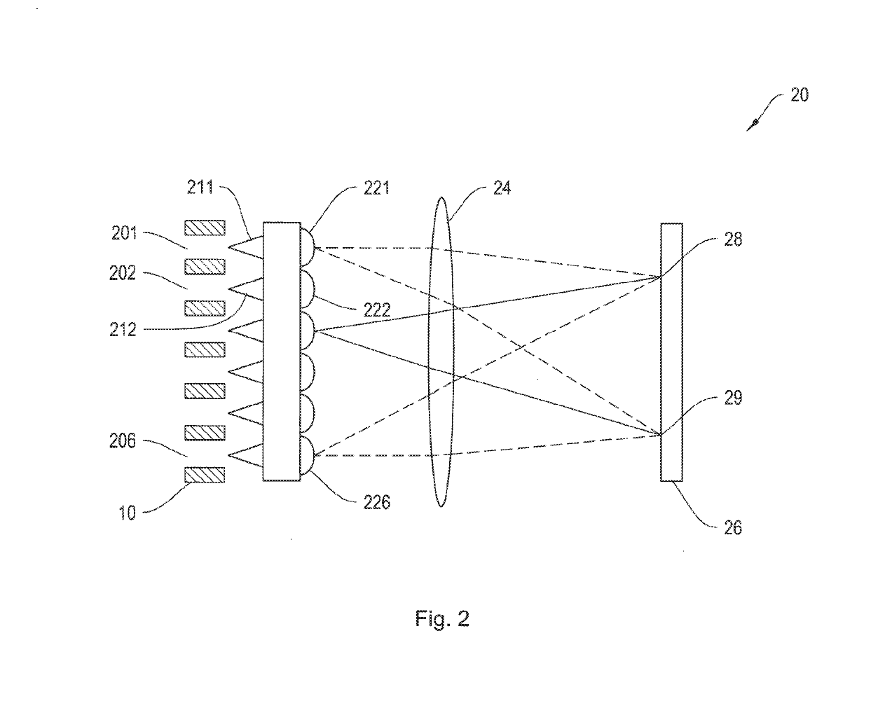

FIG. 2 shows a cross-sectional view of a color channel 20 of a projection display. The color channel 20 includes the bandwidth-enhanced laser light source 10, a two-dimensional microlens array 22, subsequently also referred to as “fly-eye” lens, with lenslets 221, 222, . . . that substantially match the spatial arrangement of the respective lasing elements 201, . . . , 206 of the laser light source 10, a condenser lens 24, and a spatial light modulator 26 which can be in form of a liquid crystal light valve, for a liquid crystal display (“LCD”) or a deformable mirror device (DMD). For example, the lenslet 221 in conjunction with the condenser lens 24 images the laser beam 211 emitted by the respective lasing elements 201 onto the active surface 28, 29 of the spatial light modulator 26. Likewise, the lenslet 222 images the laser beam 212 emitted by the respective lasing elements 202 onto the active surface 28, 29, and so on. As a result, the spectral output of all lasing elements 201, 202, . . . is superpositioned on the active surface 28, 29 of the spatial light modulator 26, forming the desired bandwidth-enhanced laser illumination for a projection display. The lenslets of the “fly-eye” lens are also designed so as to transform the circular or elliptical beams 211, 212, . . . into a substantially rectangular shape to conform to the size and aspect ratio of the modulator 26. In other words, the “fly-eye” lens array and a condenser lens deliver a uniform-intensity rectangular patch of bandwidth-enhanced light to a modulator in the image plane. In other embodiments, the color channel 20 includes a load integrator instead of the “fly-eye” lens 22.

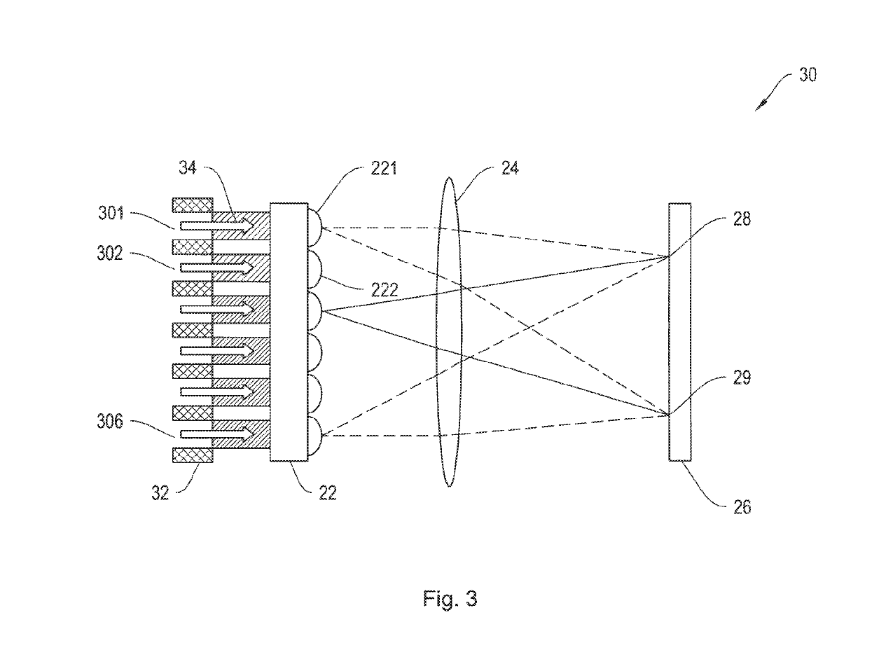

FIG. 3 shows a cross-sectional view of an alternative embodiment of a color channel 30 of a projection display. As in the example of FIG. 2, the spectral output of lasing elements 301, 302, . . . is superpositioned on the active surface 28, 29 of the spatial light modulator 26, forming the desired bandwidth-enhanced laser illumination for a projection display. Unlike the embodiment of FIG. 2, however, the light emitting array 32 is assumed to emit light in a spectral range that is not suitable for RGB projection displays, for example, in the IR spectral range. In this case, the IR emitter can be mated, in the illustrated example butt-coupled, to a nonlinear optical element 34 (such as OPO, SHG, SFG or a combination thereof) or of another type known in the art. The wavelength of the light exiting the lenslets 221, 222, . . . may be tuned by selecting the wavelength of the individual emitters 301, 302, . . . and/or by tuning the nonlinear conversion modules 34 over the optical bandwidth of the emitters. The emitters 301, 302, . . . could be IR- or UV-emitting semiconductor laser diodes or fiber lasers. Alternatively, the optical elements 34 could also be passive waveguides, such as optical fibers or a face plate, if the emitters 301, 302, . . . emit suitable R, G or B light.

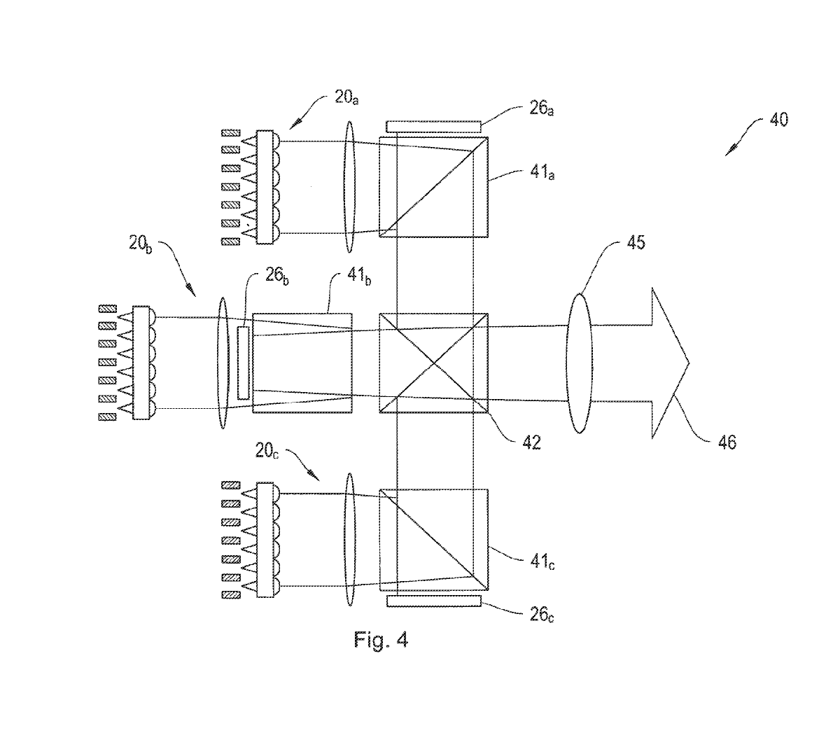

FIG. 4 depicts an exemplary laser image projection system 40 utilizing three light sources 20ₐ, 20_{b}, and 20_{c} (or alternatively 30ₐ) of the type described above with reference to FIGS. 2 and 3, respectively. Each of the exemplary light sources 20ₐ, 20_{b}, 20_{c} in system 40 produces one of the colors R, G, B and includes a beam splitter 41ₐ, 41_{b}, 41_{c} that directs the light to a respective retro-reflecting LCD 26ₐ, 26_{b}, 26_{c}. The system 40 also includes an X-cube beam combiner 42 that combines the three colors R, G, B into a single modulated RGB beam that passes through a projection lens 45 to be projected on a display screen (not shown).

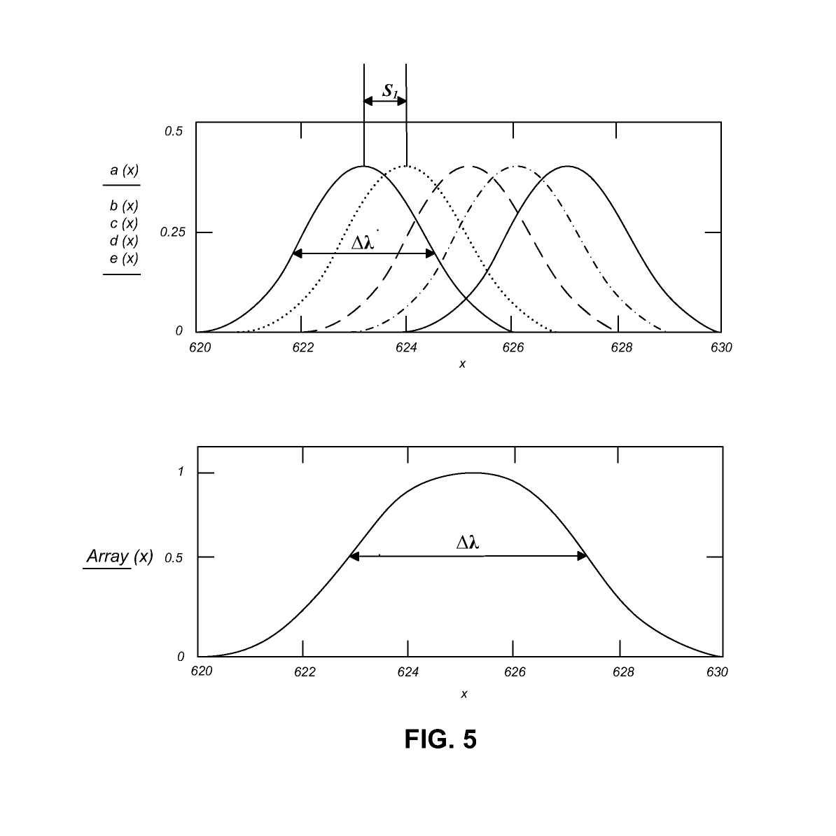

The critical parameters for designing a bandwidth-enhanced laser array (BELA) 10 include: the number n of emitters in the array, the dominant wavelength λ₀ᵢ of each emitter, the spectral separation Sᵢ between the dominant wavelength λ₀ᵢ of an emitter i and the dominant wavelength λ₀ⱼ of an emitter j being closest in wavelength, the respective bandwidth Δλᵢ of the individual emitters, and the relative output power Aᵢ of each emitter. Referring now to FIGS. 5-8, a bandwidth-enhanced laser array can be implemented by using, for example, five mutually incoherent emitters of equal amplitude. A mean spectral overlap parameter γ= Δ̅λ̅ᵢ̅/ S̅ᵢ̅ having the values of γ>1, γ=1, γ<1, and γ<<1 can be associated with the ensemble wavelength characteristic of the array.

In a first scenario with γ>1, shown in FIG. 5, there exists substantial overlap in the spectra from the individual emitters (top FIG. 5). The resulting ensemble spectrum Λ is a smoothly varying function of wavelength and virtually free of any spectral features from the individual emitters (bottom FIG. 5). This condition may be considered “ideal” for bandwidth enhancement since the spectral averaging that occurs produces a uniformly broadened distribution for γ>>1 and large n, thereby minimizing speckle.

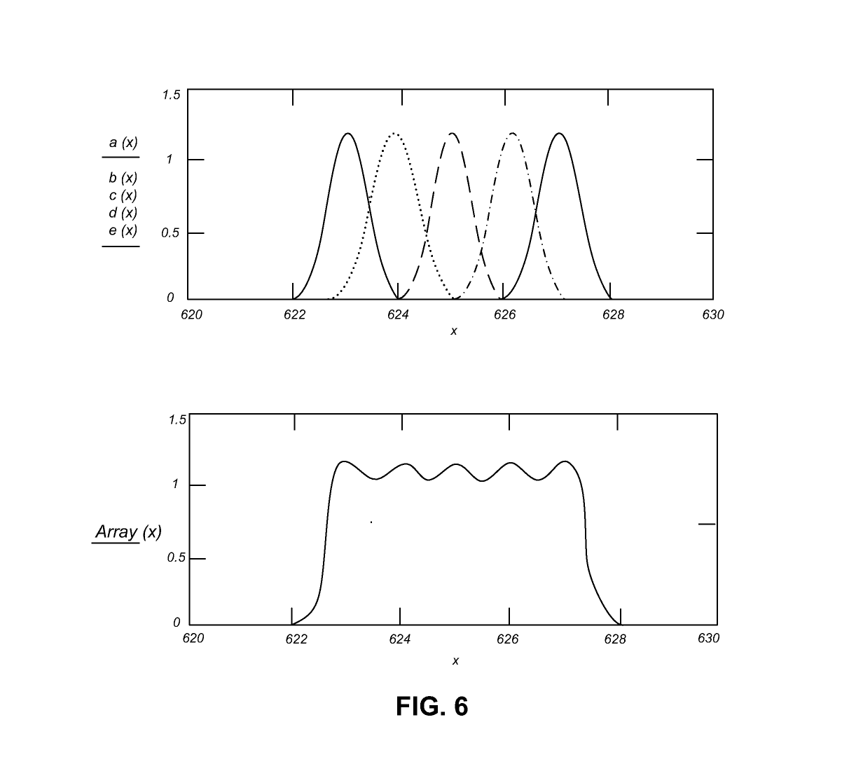

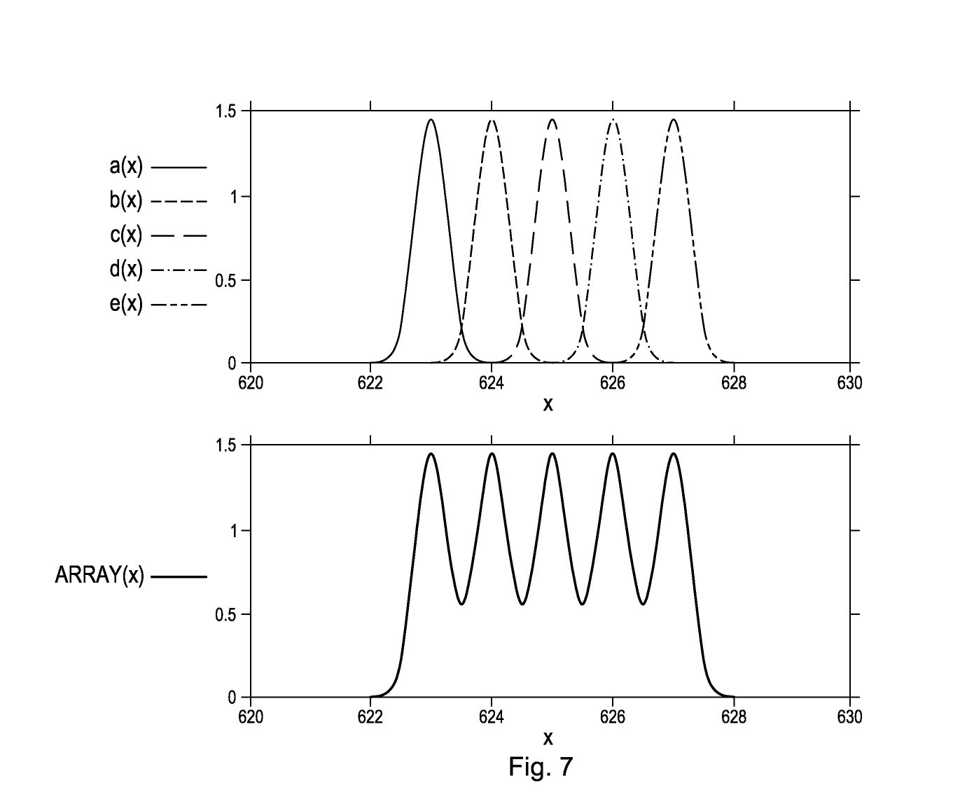

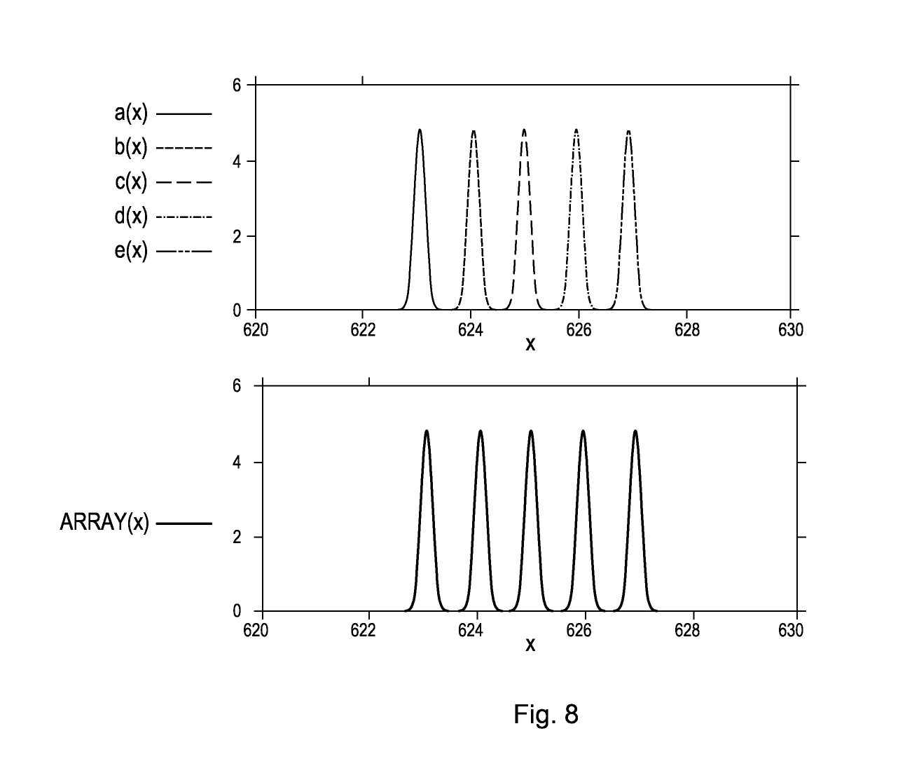

For γ equal to or less than 1, as depicted in FIG. 6 with γ=1, FIG. 7 with γ<1, and FIG. 8 with γ<<1, the ensemble spectrum Λ shown at the bottom of the respective figures becomes a rippled function with local maxima coincident with the dominant wavelengths λ₀ᵢ of the individual emitters. Values of γ less than 1 have been found to be less efficient for reducing speckle than values of γ greater than 1. Simulations using Fourier analysis suggest that coherent interference may be even more effectively suppressed with a non-uniform distribution of emitter intensities, with the possibility of eliminating speckle noise altogether.

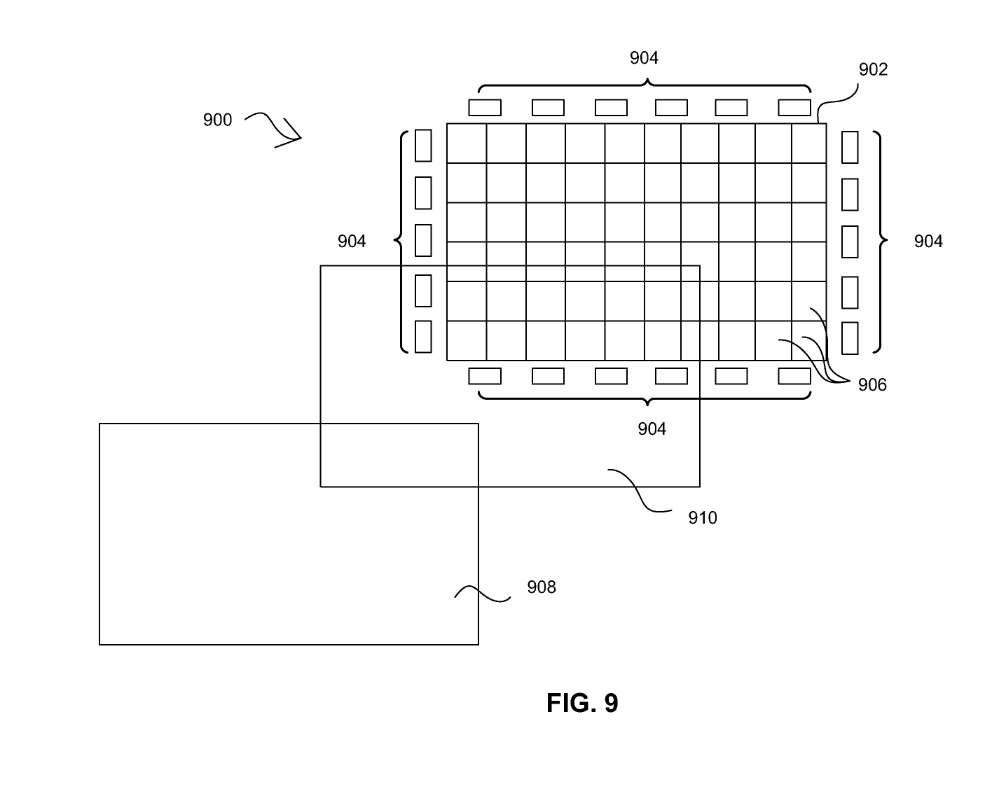

FIG. 9 is a schematic diagram of a laser illuminated backlight 900 for a liquid crystal flat panel display, according to an illustrative embodiment of the invention. The backlight includes a light guide 902 surrounded along its edges by laser assemblies 904. In one implementation, the light guide 902 includes an array of microlenses 906 formed on or molded into a forward facing surface of the light guide. Suitable light guides can be obtained, for example, from Mitsubishi Rayon, Sumitomo Chemical, Asahi Chemical, Kuraray, Nihon Zeon, and Global Lighting Technologies (MicoLens BACKLIGHTING™). In alternative implementations, the backlight includes a highly reflective rear reflector instead of, or in addition to having the microlenses 906 molded into the light guide 902.

The number of laser assemblies used and their respective positions with respect to the light guide depends on the size of the display, the desired brightness of the display, and the level of color and brightness uniformity desired across the display. For example, in various implementations, multiple laser assemblies 904 are positioned along all four edges of the light guide 902, two of the four edges of the light guide 902, or along a singe edge of the light guide 902. In alternative implementations, single laser assemblies 904 are positioned at each of the corners of light guide 902, at two of the corners, or at a single corner of the light guide 902.

The backlight 900 includes a polarizing film 908 to polarize light emitted from the backlight to enable proper light modulation by the liquid crystal display panel to which the laser illuminated backlight 900 is coupled. Optionally, the backlight 900 also includes a diffuser sheet 910 between the light guide and the polarizing film 908 to diffuse the light emitted from the backlight 900. In addition, the backlight 900 may also include an additional optional layer, a brightness enhancing film (also known as a “BEF”) between the polarizing film 908 and the diffuser sheet 910 or between the diffuser sheet 910 and the LCD panel.

The backlight 900 can be integrated with the remainder of a standard liquid crystal flat panel display module to form a complete flat panel display. For example, the backlight 900 can be coupled with a LCD display panel including an array of liquid crystal cells controlled by an active (thin-film transistor (TFT)) or passive matrix backplane disposed on a transparent substrate. The backplane and the laser assemblies are coupled to driver circuits governed by a controller circuit for controlling the intensity of the lasers and for addressing the individual liquid crystal cells. The display module also includes a color filter film, including an array of red, green, and blue color filters corresponding to respective liquid crystal cells, along with a second polarizing film, a brightness enhancing film, and a cover plate.

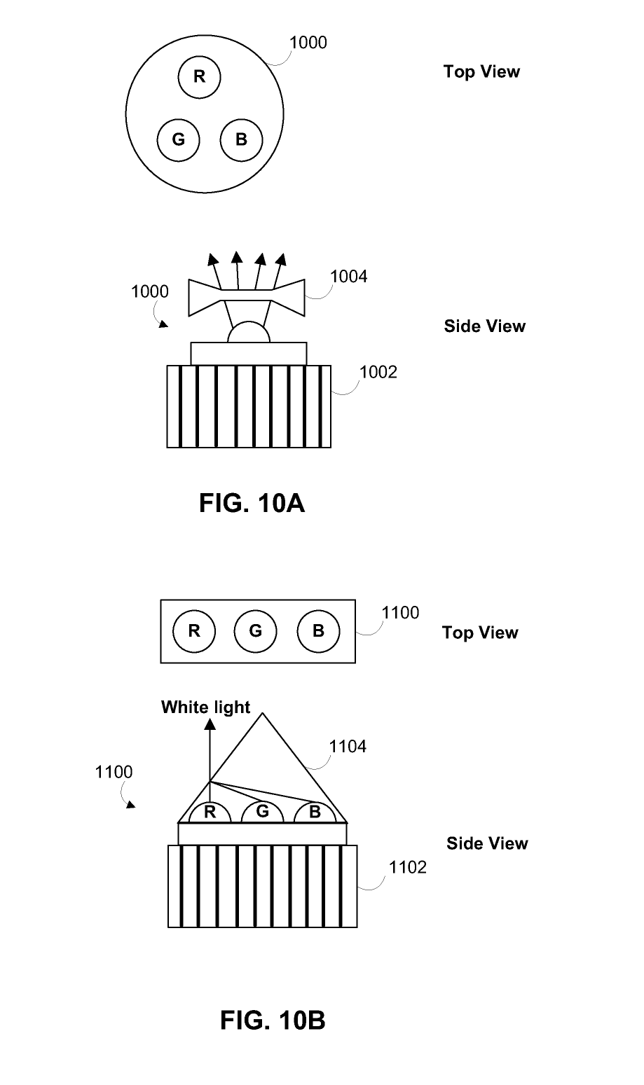

FIG. 10A is a schematic diagram of a first laser assembly 1000 suitable for use as a laser assembly 904 incorporated into the laser illuminated backlight 900 of FIG. 9. In the laser assembly 1000, individual lasers are arranged in a generally triangular fashion. As illustrated, each laser module includes red (R), green (G), and blue (B) lasers. While only a single laser of each color is depicted in FIG. 10A, each laser assembly 1000 may include one or multiple lasers of each color, each having a slightly different dominant wavelength, as described in relation to FIG. 1, to generate an ensemble wavelength suitable for reducing speckle in a resulting image. In addition, due to power outputs of the different lasers used to generate each color, each laser assembly 1000 may not have the same number of each color of laser. That is, more lasers may be required to generate the desired light output of one color than another. Lasers of a generally same color (e.g., red lasers with slightly different dominant wavelengths) may be clustered together within the assembly 1000 or they may be intermixed with lasers of other colors. Preferably, the number, ensemble wavelength, and power of the lasers are selected such that when the output of the lasers are mixed, the result is a substantially pure white light source (having a color temperature ranging from 6,500 K up to 20,000 K), which when modulated, yields an image substantially free of speckle.

The laser assembly 1000 also includes a heat sink 1002 for dissipating heat generated by the lasers incorporated into the assembly. In one embodiment, to promote diffusion of the laser light and proper color mixing within the light guide 902, the laser assembly includes an optical element, such as a concave lens 1004 positioned between the lasers and the light guide.

FIG. 10B is a schematic diagram of a second laser assembly 1100 suitable for use as the as a laser assembly 904 incorporated into the laser illuminated backlight 900 of FIG. 9. In the laser assembly 1100, individual lasers are arranged in a single dimension. As illustrated, each laser module includes red (R), green (G), and blue (B) lasers. While only a single laser of each color is depicted in FIG. 10B, each laser assembly 1100 may include one or multiple lasers of each color, each having a slightly different dominant wavelength, as described in relation to FIG. 1, to generate an ensemble wavelength suitable for reducing speckle in a resulting image. In addition, due to power outputs of the different lasers used to generate each color, each laser assembly 1100 may not have the same number of each color of laser. That is, more lasers may be required to generate the desired light output of one color than another. Lasers of a generally same color (e.g., red lasers with slightly different dominant wavelengths) may be clustered together within the assembly 1100 or they may be intermixed with lasers of other colors. Preferably, the number, ensemble wavelength, and power of the lasers are selected such that when the output of the lasers are mixed, the result is a substantially pure white light source, which when modulated, yields an image substantially free of speckle.

The laser assembly 1100 also includes a heat sink 1102 for dissipating heat generated by the lasers incorporated into the assembly. In one embodiment, to promote diffusion of the laser light and proper color mixing within the light guide 902, the laser assembly 1100 includes an optical element, such as a equilateral prism or spherical asphere lens, positioned between the lasers and the light guide 902. A spherical asphere lens is capable of converting a collimated beam of light having a Gaussian emission spectrum to a horizontal beam of light having a substantially uniform emission spectrum.

In alternative display embodiments, the light sources described above may be arranged in an N×M matrix to form a direct backlight for the display, without using an intervening light guide.

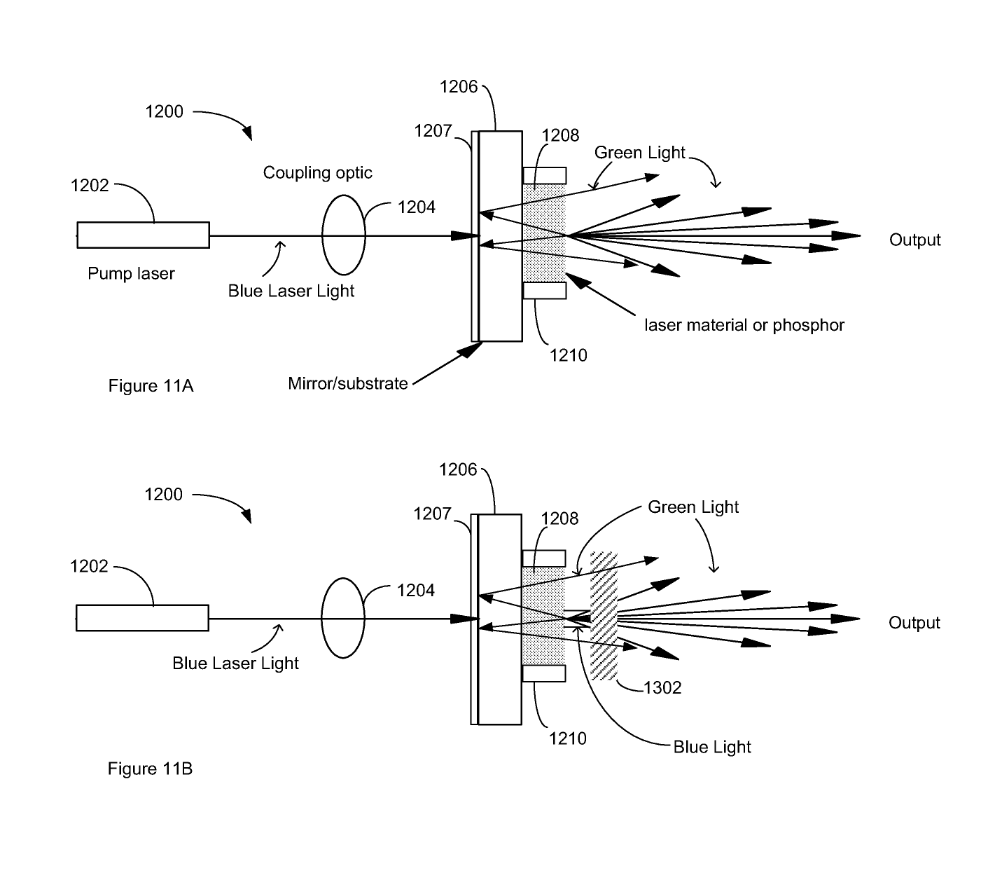

FIG. 11A is a schematic diagram of a first illustrative blue-diode laser pumped green light source 1200 suitable for inclusion in the laser modules of FIGS. 10A and 10B, according to an illustrative embodiment of the invention. The green light source 1200 includes a semiconductor diode laser 1202 emitting light in an optical path having a dominant wavelength within the blue spectral region, a substrate 1206 positioned in the optical path of the semiconductor diode laser 1202, and a light emitting material 1208 coupled to the substrate 1206. The material 1208 provides green light emissions. In particular, the light emitting material 1208 is selected to absorb light emitted by the semiconductor diode laser 1202 and, in response, to emit light having a dominant wavelength within the green spectral region. Exemplary light emitting materials 1208 are described further below.

The green light source 1200 is pumped by the semiconductor diode laser 1202, or an array of such lasers 1202, that emits light in the blue region of the electromagnetic spectrum, i.e., light having a dominant wavelength between about 430 nm to about 490 nm (referred to as the “blue spectral region”). Nichia Corporation, of Tokushima, Japan, offers exemplary suitable blue semiconductor diode lasers, which emit light at about 440-455 nm and about 468-478 nm. The former laser provides about 500 mW of power. Optional coupling optics 1204, for example one or more cylindrical lenses, couple the blue light emitted by the semiconductor diode laser(s) 1202 with the substrate 1206.

The green light source 1200 includes components that assist in directing light emitted by the light emitting materials 1208 in a desired direction. The substrate 1206 is coated with a layer 1207 on its pumped side (i.e., the side facing the semiconductor diode laser(s) 1202), which is highly reflective in the “green spectral region” (i.e., light having a wavelength of about 490 nm to about 560 nm). Some green light emitted by the material 1208 may be emitted in the direction of, and thus be reflected by, the reflective layer 1207. In some embodiments, a hollow polished capillary tube 1210 confines the substrate 1206. The capillary tube 1210 serves to direct light emitted by the light emitting material 1208 in a forward direction (i.e., in a direction away from the reflective layer 1207). Other forms of light guiding, other than or in addition to capillary tube 1210, may be employed in the green light source 1200 to direct light in a forward direction, without departing from the scope of the invention.

The coupling of the light emitting material 1208 to the substrate 1206 may take various forms. In one embodiment, a side of the substrate 1206, opposite that of the reflective layer 1207, is coated with a light emitting material 1208, such as a phosphor including semiconductor materials or rare-earth elements (e.g., a single crystal light emitting material or a nanoparticle powder). In another embodiment, instead of being coated with a light emitting material 1208, the substrate 1206 can be doped directly with a light emitting material 1208, e.g., rare-earth ions, in which case light emitted by the light emitting material 1208 is a result of an amplified spontaneous emission (ASE).

In one embodiment, the green light source emits light through down conversion. For example, blue photons excite an electron from a ground state to an upper excited-state, then the electrons decay into a lower excited state before emitting a green photon to return to the ground state.

In some embodiments, the light emitted by the light emitting material 1208 is in the form of random laser radiation/emission (i.e., laser radiation/emission generated, not using a traditional resonator with aligned mirrors providing optical feedback, but rather relying on scattering for optical feedback). The gain medium may be a powder or suspension of particles that provide their own optical coupling and feedback and typically generate multiple overlapping output beams from many different optical paths. Hence, the output achieved by random laser radiation/emission often contains many individual frequencies that are uncorrelated and have a short coherence length, leading to negligible speckle artifacts. Enhanced optical feedback in the gain medium may be obtained from strongly scattering nanoparticles or by incorporation of a matrix of spherical particles exhibiting resonant enhancement of their intrinsic Mie scattering process. An exemplary Mie scattering matrix is formed from micron-sized polystyrene or silica spheres assembled as a matrix, where the light emitting material 1208 is dispersed between the spheres of the matrix. Exemplary light emitting materials 1208 for providing random laser radiation/emission include rare-earth doped material powders, rare-earth oxide powders, and phosphor powders, which may also be rare-earth based. In some embodiments, a powder used as material 1208 is refined to a particle size in the tens to hundreds of microns in diameter. In some embodiments, a powder used as material 1208 is refined to a particle size in the sub-micron size regime. Sub-micron sized particles may be manufactured using thermally driven precipitation, pyrolosis, gas phase condensation, and calcining techniques.

In some embodiments, phosphors are manufactured in a powdered form and then used to coat the substrate 1206 with a relatively thick film, e.g., 5 μm to 10 μm. Suitable particle sizes within the film may range from the nanoscale regime to agglomerated masses of particles that approximate bulk material. The luminescent efficiency of the phosphor depends strongly on the particle size. Bulk materials and nanomaterials have similar luminescent efficiencies, whereas amorphous or semi-amorphous materials with sub-micron particle sizes suffer from increased optical scattering and reabsorption losses and are therefore less efficient. In the single molecule limit, the particles act in isolation, almost as if quantum confined, and the efficiency rises dramatically. Surface recombination losses also play a role and are lower in the nanoparticle regime. For implementations resulting in random lasing, the light emitting material is preferably formed from nano-sized particles.

Suitable rare-earth ions and their respective absorption and emission parameters are provided in the following table:

| | Absorption | | Emission | |
|---|---|---|---|---|
| Ion | λₐ (nm) | Transition | λₑ (nm) | Transition |
| Pr³⁺ | 444 | ³H₄ → ³P₁ | 523 | ³P₀ → ³H₅ |
| | 479 | ³H₄ → ³P₀ | 523 | ³P₀ → ³H₅ |
| Nd³⁺ | 429 | ³I_{9/2} → ⁴G_{11/2} | 522 | ²G_{9/2, 7/2} → ⁴I_{9/2} |
| | 485 | ³I_{9/2} → ⁴G_{9/2} | 522 | ²G_{9/2, 7/2} → ⁴I_{9/2} |
| Sm³⁺ | 452 | ⁶H_{5/2} → ⁴F_{5/2} | 530 | ⁴F_{3/2} → ⁶H_{5/2} |
| | 462 | ⁶H_{5/2} → ⁴I_{13/2} | 530 | ⁴F_{3/2} → ⁶H_{5/2} |
| Tb³⁺ | 488 | ⁷F₆ → ⁵D₄ | 543 | ⁵D₄ → ⁷F₅ |
| Ho³⁺ | 450 | ⁵I₈ → ⁵F₁ | 547 | ⁵S₂ → ⁵I₈ |
| | 450 | ⁵I₈ → ⁵F₁ | 543 | ⁵F₄ → ⁵I₈ |
| Er³⁺ | 446 | ⁴I_{15/2} → ⁴F_{3/2} | 554 | ⁴S_{3/2} → ⁴I_{15/2} |
| | 452 | ⁴I_{15/2} → ⁴F_{5/2} | 554 | ⁴S_{3/2} → ⁴I_{15/2} |
| | 490 | ⁴I_{15/2} → ⁴F_{7/2} | 554 | ⁴S_{3/2} → ⁴I_{15/2} |

Three preferred rare-earth ions include Erbium (Er³⁺), Homium (Ho³⁺), and Preasodymium (Pr³⁺). Each can be pumped at about 450 nm and emit photons in the green spectral region (554 nm, 543 nm or 547 nm, and 523 nm, respectively). In one implementation, the light emitting material is an Er³⁺-doped phosphate glass. In another implementation, the light emitting material includes a Tb³⁺-doped phosphor, such as a P43 or P53. In another implementation, the light emitting material includes a Ce³⁺-doped YAG, such as a P46, which may be incorporated into a Mie scattering matrix. In another implementation, the light emitting material includes a rare-earth oxide powder based on one of the three preferred rare-earth ions.

FIG. 11B shows schematically a second illustrative blue-diode laser pumped green light source 1300 suitable for inclusion in the laser modules of FIGS. 10A and 10B, according to an embodiment of the invention. The second illustrative blue-diode laser pumped green light is identical to the light source 1200 of FIG. 11A, other than it includes one additional optical component 1302. In one implementation, the additional optical component 1302 is a filter for filtering out light that would otherwise be emitted by the light source outside of the green spectral region, for example, blue light passing through the substrate that is not absorbed by the light emitting material 1208 which would otherwise continue onward towards a viewer. In addition, depending on the light emitting characteristics of the light emitting material 1208, photons in other spectral regions may also be emitted in addition to photons in the green spectral region. In implementations in which a substantially pure green light source is desired (for example, if the light were used in a field sequential color-based display), the optical filter can remove the light contamination. In another embodiment, the additional optical component 1302 includes an output coupler. The output coupler reflects a predetermined portion of the emitted light back towards the reflective layer 1207 to generate a degree of resonance (“quasi-resonance”), thereby selecting and narrowing the desired green output wavelength. The output coupler may also be configured to reflect light at undesirable frequencies.

In implementations in which multiple light sources of multiple colors are simultaneously illuminated to form a white light, a filter or optical coupler is less important and may even be a waste of power. Instead, if the emission characteristics of the green light source are well characterized, the power of the remaining light sources can be adjusted to compensate for any non-green light emitted by the green light source.

While the invention has been disclosed in connection with the preferred embodiments shown and described in detail, various modifications and improvements thereon will become readily apparent to those skilled in the art. Accordingly, the spirit and scope of the present invention is to be limited only by the following claims.

1. An apparatus for emitting green light comprising:
a semiconductor diode laser emitting light in an optical path having a dominant wavelength within the blue spectral region;
a substrate positioned in the optical path of the semiconductor diode laser; and
a material coupled to the substrate selected to absorb light emitted by the semiconductor diode laser and, in response, to emit light having a dominant wavelength within the green spectral region.

2. The apparatus of claim 1, wherein the material comprises a phosphor deposited on a surface of the substrate.

3. The apparatus of claim 2, wherein the phosphor comprises a semiconductor material having a band gap in the green spectral region.

4. The apparatus of claim 2, wherein the phosphor comprises at least one of a CdS, a CdSe, a ZnS, or a ZnO composition.

5. The apparatus of claim 2, wherein the phosphor comprises a composition having the form CdSₓSe₁₋ₓ.

6. The apparatus of claim 1, wherein the material comprises a rare-earth ion dopant.

7. The apparatus of claim 6, wherein the dopant comprises one of a Pr³⁺, Nd³⁺, Sm³⁺, Tb³⁺, Ho³⁺, Er³⁺.

8. The apparatus of claim 1, wherein the material emits light as an amplified spontaneous emission.

9. The apparatus of claim 1, wherein the material is coupled to a first side of the substrate, further comprising a reflective surface coating an opposing side of the substrate.

10. The apparatus of claim 1, comprising an optical filter placed beyond the substrate in the optical path to filter out light not in the green spectral region.

11. The apparatus of claim 1, comprising an output coupler placed beyond the substrate in the optical path to reflect at least a portion of light in the green spectral region back towards the substrate to generate quasi-resonant green light.

12. The display of claim 1, wherein the substrate comprises a Mie scattering matrix comprising spherical particles, the material being dispersed between the spherical particles.

13. The display of claim 1, comprising a component for directing light emitted by the material in a desired direction.

14. An apparatus comprising at least one lighting module for a display, the at least one lighting module including:
an array of red laser light sources;
an array of blue laser light sources; and
an array of green light sources, each of the green light sources comprising
a semiconductor diode laser emitting light in an optical path having a dominant wavelength within the blue spectral region,
a substrate positioned in the optical path of the semiconductor diode laser, and
a material coupled to the substrate selected to absorb light emitted by the semiconductor diode laser and, in response, to emit light having a dominant wavelength within the green spectral region.

15. The apparatus of claim 14, wherein, for at least one of the array of red laser lights sources and the array of blue laser light sources,
at least one of the laser light sources of the array has a dominant wavelength λ₀ᵢ and a spectral bandwidth Δλᵢ;
the dominant wavelength of at least one laser light source of the array is wavelength-shifted with respect to the dominant wavelength of at least one other laser light source of the array; and
emissions from said laser light sources of the array, when combined, have an ensemble spectrum Λ with an overlap parameter γ= Δ̅λ̅ᵢ̅/ S̅ᵢ̅, with
Δ̅λ̅ᵢ̅ being a mean spectral bandwidth of the laser light source array,
S̅ᵢ̅ being a mean wavelength shift between the dominant wavelengths λ₀ᵢ of the at least one laser light source and the at least one other laser light source, and
Δ̅λ̅ᵢ̅ and S̅ᵢ̅ of the array being selected so that γ≧1.

16. The apparatus of claim 14 comprising:
a light guide, the at least one lighting module disposed about the perimeter of the light guide for injecting light into the light guide; and
an array of liquid crystal light modulators for modulating light exiting the light guide.

17. The apparatus of claim 14, wherein the arrays are configured to emit light which, when combined, is substantially white.

18. The apparatus of claim 14, wherein, for each of the green light sources, the material comprises a phosphor deposited on a surface of the substrate, the phosphor comprising a semiconductor material having a band gap in the green spectral region.

19. The apparatus of claim 14, wherein the material of each of the green light sources comprises a rare-earth ion dopant.

20. The apparatus of claim 14, wherein, for each of the green light sources, the material is coupled to a first side of the substrate, each of the green light sources further comprising a reflective surface coating an opposing side of the substrate.

21. The apparatus of claim 14, comprising, for each of the green light sources, an output coupler placed beyond the substrate in the optical path to reflect at least a portion of light in the green spectral region back towards the substrate to generate quasi-resonant green light.

22. The display of claim 14, wherein, for each of the green light sources, the substrate comprises a Mie scattering matrix comprising spherical particles, the material being dispersed between the spherical particles.
